(19) United States
(12) Patent Application Publication
(10) Pub. No.: US 2024/0269788 A1
(43) Pub. Date: Aug. 15, 2024

(54) PLANAR POSITIONING APPARATUS AND WORKBENCH

(71) Applicant: PHYSIK INSTRUMENTE (PI) GMBH & CO. KG, Karlsruhe (DE)

(72) Inventors: Stefan Schulz, Karlsruhe (DE); Thomas Haase, Steinweiler (DE)

(21) Appl. No.: 18/290,302

(22) PCT Filed: May 30, 2022
(86) PCT No.: PCT/EP2022/064562

§ 371 Date: Nov. 12, 2023

(30) Foreign Application Priority Data
Jun. 15, 2021 (DE) 10 2021 115 415.4

(51) Int. Cl. B23Q 3/18; B23Q 3/02; B23Q 17/00

(52) U.S. Cl. CPC B23Q 3/186; B23Q 3/02; B23Q 17/003

(57) ABSTRACT

The invention relates to a planar positioning apparatus for positioning loads on a predetermined plane, said positioning apparatus comprising:—a base plate having a flat surface that extends parallel to and at a specific distance from the predefined positioning plane, thus defining same;—four identical linear guides/drives which are collinearly fastened to or on the base plate in pairs parallel to the two other linear guides/drives; and—a parallel kinematic unit which comprises a load platform, is disposed between the parallel linear guides/drives, and is rotationally connected to the rotors of all linear drives via one passive joint each.

The invention relates to a planar positioning device and a corresponding workbench for highly precise positioning of bodies in a predetermined plane.

Positioning devices for positioning bodies in a plane have long been known in a wide variety of forms and in mass practical use, for example in many types of measuring devices or machine tools or various types of systems for the manufacture of electrical engineering and electronics products.

Many of these fields of application involve highly precise positioning of the corresponding body in relation to a measuring device or a machining tool. Such positioning devices or X-Y tables have therefore always been subject to high precision requirements. These requirements have become even more stringent in recent decades, particularly in the course of the ever-increasing miniaturization of structural elements in semiconductor technology, and are now in the nanometre range.

Known positioning devices are usually stacked, single-axis systems, in which at least two linear drives are arranged one above the other. Positioning errors can add up in such stacked systems, which is particularly problematic with extreme precision requirements. In addition, the parts of such stacked systems are subject to different dynamic requirements, for example given that a lower drive has to support and move the upper drive above it as well as the body to be moved, whereas the upper drive only has to cope with the mass of the body.

In particular, it is difficult to achieve a low height in stacked systems, even though this is desirable for certain applications.

So-called parallel kinematic units are sometimes used in high-precision positioning devices and are characterized by a low moving mass and thus high dynamics, low drive forces and high rigidity compared to other drives. Advanced positioning devices or X-Y tables are, for example, disclosed in U.S. Pat. No. 6,674,671 B1, U.S. Pat. No. 7,898,204 B2, CN 102 615 514 A, CN 101 104 272 A, CN 103 101 050 B and CN 104 317 218 A.

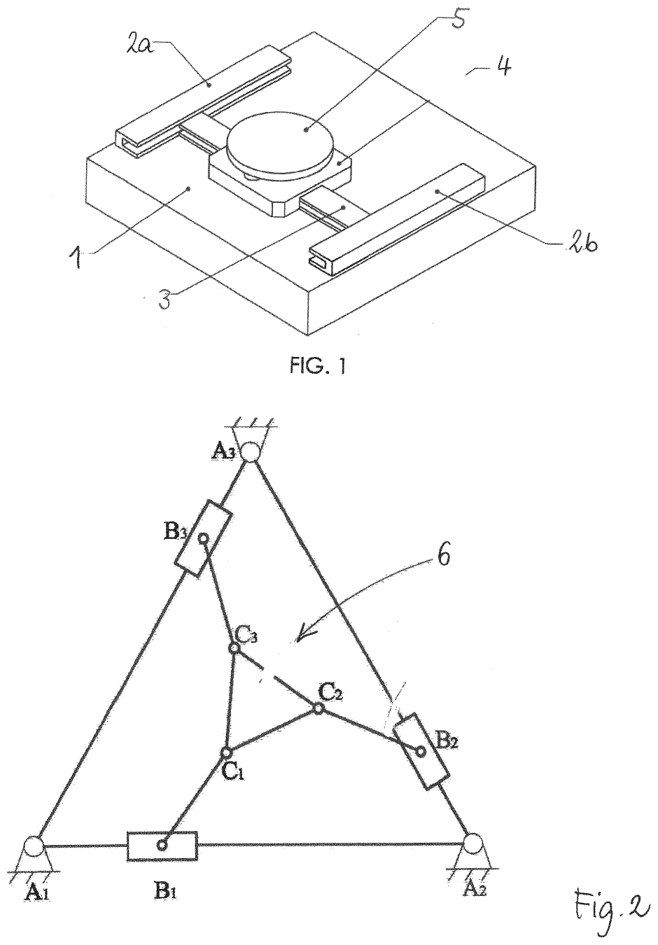

The prior art includes planar positioning devices of the basic type outlined in FIG. 1, in which, in an H-shaped arrangement, two parallel, spaced apart linear drives 2a and 2b on a carrier 1 guide a third linear drive 3 between them with a positioning direction perpendicular to the other drives 2a and 2b. The third drive 3 moves a workbench 4, on which, for example, an additional rotary table 5 is arranged.

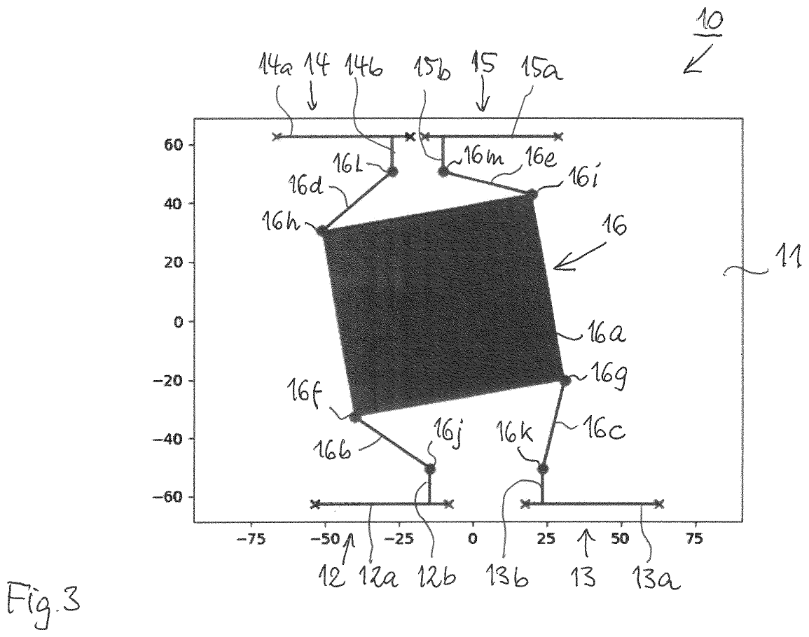

It is also known to construct a planar positioning device with three linear drives arranged on the sides of an equilateral triangle, as outlined in FIG. 2. Here, a first linear drive B1 is provided, which runs between two fixed points A1 and A2 on a carrier (not shown), a second linear drive B2 is provided, which runs between the point A2 and a third fixed point A3 on the carrier, and a third linear drive B3 is provided, which runs between A1 and A2. A parallel kinematic unit 6 with three internal rotary joints C1, C2 and C3 is mounted on rotary joints on the linear drives. A workbench or substrate holder (also not shown), which can be precisely positioned via the three drives and the parallel kinematic unit guided between them, can be mounted in the middle of the region surrounded by the connections between C1, C2 and C3.

Against the background of this prior art, the object of the invention is to provide a further improved planar positioning device, which is to be characterized in that it enables a high degree of positioning precision and speed and correspondingly accurate detection of the position of the moving body by means of corresponding sensors. In addition, the design of an improved planar positioning device should be easily adaptable to different tasks or areas of use and be cost-effective to produce for different applications.

This object is achieved by a planar positioning device having the features of claim 1. Expedient further developments of the inventive concept are the subject of the dependent claims. A positioning table, for which the novel planar positioning device is used, is further provided.

In order to produce a planar positioning device that is as flat as possible, a planar parallel kinematic unit is used according to a first aspect of the invention. The kinematics are based on an extended planar 3-PRR parallel kinematic unit. This consists of three identical kinematic chains that connect the fixed base with the moving work platform. Each kinematic chain consists of a driven prismatic joint (P) and two passive rotary joints (R) connected in series. The planar 3-PRR parallel kinematic unit is known from numerous publications.

Another fundamental aspect of the invention relates to the provision of four drives and the arrangement of these drives. Two drives run on a common geometric axis or line and are parallel to the two other drives, which also run on a common axis.

By moving the two drives apart from and towards each other on a common axis, the moving platform, which lies between the two axes, is moved away from or towards this axis. This can be compared to a pair of scissors whose common centre of rotation moves backwards or forwards when opening and closing. If the distance between the drives on the common axis is maintained and the drives are moved on the parallel axis, it is possible to rotate the moving platform about the vertical axis.

An advantageous feature here is the symmetry, i.e. each of the four drives can be assumed to be a redundant drive. Three drives are required to cover three degrees of freedom.

In one embodiment of the invention, the fourth, redundant drive can be used to apply a predetermined resistance to the movement of the object in the form of motion attenuation or “preload” of the system. A corresponding control regime is readily apparent to a person skilled in the art due to the function of the fourth drive, taking into account the desired attenuation degree or preload value, and is therefore not described in more detail here.

The drives mentioned, to also referred as linear guides/drives below, are on a base plate having a flat surface that extends parallel to and at a specific distance from the predetermined positioning plane, thus defining same. It should be noted that a separate base plate can also be provided for each of the collinear linear guides/drives provided that these two base plates have surfaces that lie in a common geometric plane. It is also not strictly necessary for the base plates to be completely flat as long as their shape ensures that the linear guides/drives operate in a common plane and the movements of the parallel kinematic unit between the linear guides can take place freely over the surface of the base plate.

In one embodiment of the invention, the load platform of the parallel kinematic unit is designed as a rectangular, in particular square, plate, on or near the corners of which a passive joint is provided. Each joint is respectively rotationally connected to a connecting arm of the parallel kinematic unit, the other end of which is connected to the joint on one of the linear drives. All support arms are advantageously identical here.

In a further advantageous embodiment, the collinear linear guides/drives respectively comprise a common linear guide and two linear motors with guide carriages as sliders, which are arranged spaced apart on the guide and moveable collinearly and independently of one another in both directions.

In particular, the collinear linear guides/drives comprise a Halbach array of permanent magnets that is common to both linear motors and extends substantially over the entire length of the linear guide. Alternatively, “conventional” magnetic tracks are also possible. Both Halbach arrays and conventional magnetic tracks can be designed on one side and in a U-shape.

In principle, it is also possible, in reversal of the principle described above, to provide the sliders with permanent magnets and the linear guides with coils, which, similarly to the drives mentioned, are electrically controlled and the corresponding magnetic field changes of which induce a movement of the magnets in the sliders and thus of the sliders themselves.

Here, it is provided that two drives use both the same linear guide and the same Halbach array. This has the advantage of considerably reducing the installation space and costs. The common linear guide also provides increased precision thanks to the inherent shape and position tolerance of the drives to each other.

In a practical embodiment, the drives are 3-phase linear motors and are fixed on one side to a linear guide, which allows the degree of freedom parallel to the common axis and blocks all other degrees of freedom. The drives are positioned on the Halbach array in such a way that the conductor paths of the linear motors run perpendicular to the magnetic field and a resulting force is applied precisely in the direction of the axis. The drives are connected to the moving work platform on the side of the linear guides in particular via two bearings and a passive link.

In one embodiment of the invention, two sensor concepts are implemented. On the one hand, sensors are placed on the drives that measure the position of the drive via a linear position scale or a linear scale (“1D grid”) on the base plate. In this case, two drives advantageously use the same 1D grid. The position of the moving work platform can then be deduced from the measured position of the drives using the forward kinematics. On the one hand, the joint use of the 1D grid saves costs and, on the other hand, it increases accuracy due to its clear shape and position.

For the second sensor concept, a two-dimensional or XY position scale (“2D grid”) is mounted below the moving work platform and a sensor (a board with 1D sensors which can then be used to determine the 2D position) in the centre of the base plate. This makes it possible to directly deduce the position of the work platform. Using the inverse kinematics method (reverse kinematics), the positions of the drives can also be calculated therefrom.

There are preferably three 1D sensors, which can detect the 3D position, i.e. X and Y position coordinates as well as rotation about the Z axis, on the board. The second sensor concept is very precise, as the actual position of the slider is measured “behind” the elements guide, arms, roller bearings, . . . etc. This increases the absolute precision of the system.

The possible absolute redundancy in the measurement should be highlighted in the aforementioned sensor concept. It is possible to either use only the first sensor concept and to measure the positions of the drives in order to thus determine the position of the moving work platform. Or the second sensor concept is used and the position of the moving work platform is measured directly.

A combination of the two is in particular also advantageous in order to increase, for example, positioning precision. For calibration, both measuring methods can, for example, be used in order to detect and compensate for deformations, play in the joints, thermal or mechanical expansion or tolerance-related displacements. Switching between the sensor concepts during operation is achieved by integrating both systems without the need for wiring.

The sensor redundancy enables offsets in the axes and play in the joints and so on to be detected. It is also possible to determine the proximity to possible singularities. Finally, the forward kinematics can also be handled more easily and therefore more quickly thanks to the additional sensors.

In order to achieve the options outlined above, the planar positioning device comprises, in one embodiment, a position determining device, which is connected at the input side to the position sensors on the linear guides/drives and the three-dimensional position sensor under the work platform and is designed for pre-determined processing of the respective position signals, in particular selectively only the signals of the position sensors on the linear guides/drives or only the position signals of the two-dimensional position sensor on the load platform or the signals of all position sensors combined or in the sense of a calibration of the one sensor type by the other sensor type.

In addition to the corresponding statements above, we would like to make reference here to further advantages of the proposed solution, which can be achieved at least in specific embodiments:

The kinematic redundancy (additional drive) can (for example through additional sensors) be used for error detection or for calibrating the kinematics such that more precise positioning is achieved despite play in the system. The kinematic redundancy can also be used, if necessary, to cross singularities. The integrated symmetry allows each of the drives to be replaced without any loss of performance.

The symmetrical design (mirror symmetry of the parallel axes) enables a symmetrical working range. In addition, the design can be installed in any version without any measurable changes in performance. The use of common linear guides, Halbach arrays and 1-D grids reduces costs and provides greater positioning precision as these do not now have to be aligned against each other (as would be necessary if separate linear guides, Halbach arrays and grids had been used).

In terms of measurement technology, there is the advantage of being able to choose between indirect and direct position measurement. Both methods have different advantages. Whilst indirect position measurement is easier to carry out and provides the position of the drives straight away, which is also controlled, the position of the work platform first has to be determined (through numerical methods) and this is very time-consuming. On the other hand, if direct position measurement is used, the position of the work platform can de determined directly from the sensor signals. The position of the drives can also be easily calculated (quickly and not time-consuming).

However, measurement errors in the position of the work platform are increasingly transferred to the position of the drives by the kinematics and can lead to instabilities in the control system. A more complex control concept is required here. During long-term operation of both position measurements (direct and indirect at the same time), the positioning precision can be improved by averaging or filtering the measurement results (resolution improvement by averaging, noise reduction through filters, etc.). During alternating operation of the position measurements (direct/indirect), it is possible to calibrate the system, i.e. to detect deformations, play in the joints, thermal or mechanical expansion or tolerance-related displacements and to be able to compensate for them by storing them in look-up tables.

The sensors in the fourth (redundant) drive provide the same advantages. This sensor signal can be used for calibration, for parameter identification (for the control system) and to improve the positioning precision. It can also be used as an “observer” for complex control concepts. The additional sensor also provides the option of status and error monitoring.

Further advantages and expediencies of the invention are given in the following description of the figures. In the figures:

FIG. 1 shows a schematic diagram of a known planar positioning device,

FIG. 2 shows a schematic diagram of a known further planar positioning device,

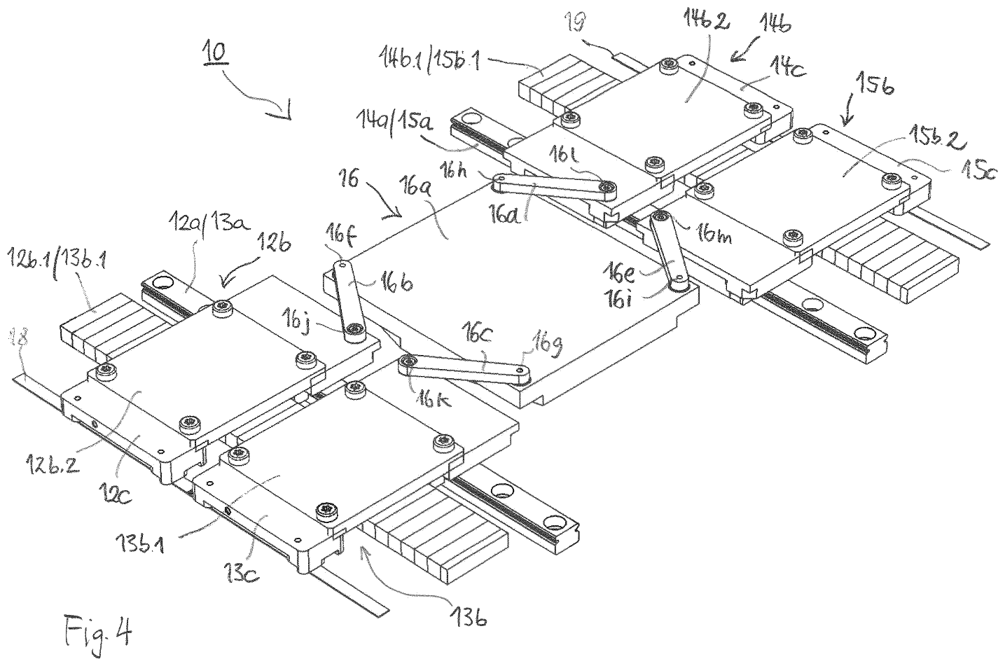

FIG. 3 shows a schematic diagram to explain the present invention,

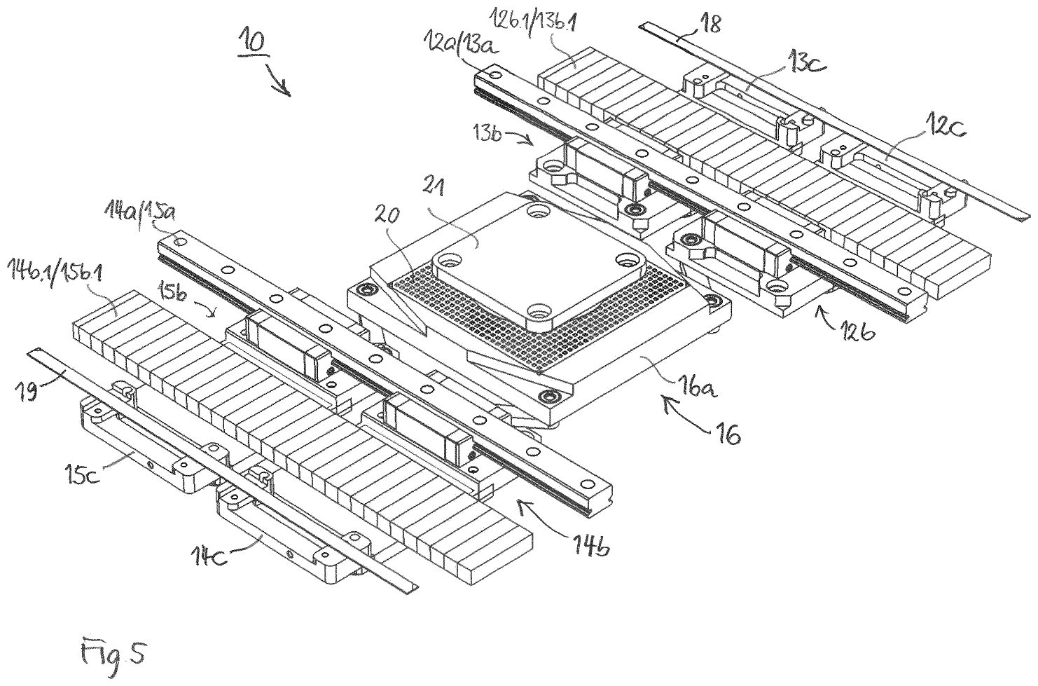

FIG. 4 shows a general view of a planar positioning device according to one embodiment of the invention, looking at a first surface of same,

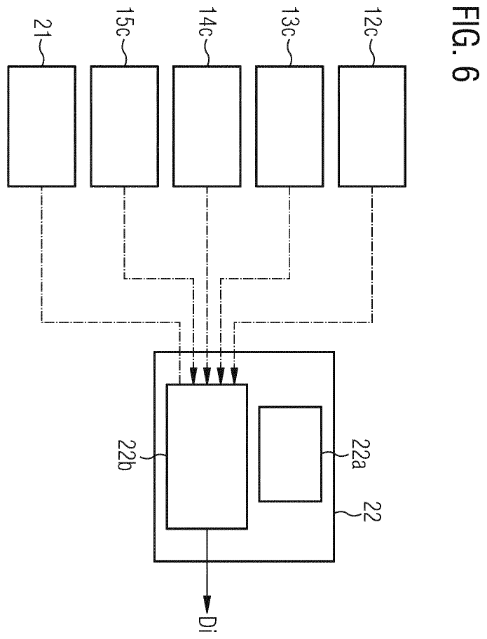

FIG. 5 shows a general view of the planar positioning device according to FIG. 4, looking at the other surface, and

FIG. 6 shows a schematic block diagram for explaining exemplary position signal processing with a planar positioning device in one embodiment of the invention.

FIG. 3 shows a schematic diagram of the basic structure of a planar positioning device 10 according to the invention, which is mounted on a base plate 11. The device 10 comprises four guides/drives 12, 15, which respectively comprise a linear guide or guide rail 12a-15a and a slider 12b-15b. In each case, two of the linear guides 12a, 13a or 14a, 15a are arranged collinear to each other, and the pairs of collinear linear guides run parallel to each other with a distance between them.

In the distance area between the pairs of collinear linear guides 12a, 13a/14a, 15a, there is a parallel kinematic unit 16 rotationally connected to the sliders 12b/15b. It comprises a load platform 16a and four connecting arms 16b—16e for rotationally connecting the load platform to respectively one of the sliders 12b-15b. The connecting arms are connected to the load platform and to the sliders via rotary joints 16f-16i on the four corners of the load platform or identical rotary joints 16j-16m on the sliders.

The operating principle of this planar positioning device is described above.

FIGS. 4 and 5 respectively show a general view of one exemplary embodiment of the planar positioning device 10 according to the invention (with the exception of the measurement and control electronics and peripheral components) in a plan view (FIG. 4) and bottom view (FIG. 5). The same reference numbers are used for identical or functionally identical components to the schematic diagram in FIG. 3 as in that figure.

In the design shown here, the planar positioning device 10 comprises, mounted on a base plate (not shown here), a first guide rail, which (according to the designation of FIG. 3) is labelled 12a/13a, and a second guide rail 14a/15a arranged parallel thereto with a distance area between them. Running parallel to the two guide rails is an elongated arrangement of permanent magnets arranged in rows with alternating polarity, generally referred to as a Halbach array. In accordance with the designation of the guide rails, the Halbach arrays are labelled 12b.1/13b.1 or 14b.1/15b.1. The Halbach arrays 12b. 1/13b.1 and 14b. 1/15b. 1 are drive components of the planar positioning device 10. In relation to the centre of the arrangement even further out, a linear optical position scale 18 or 19 also runs parallel to the respective guide rails.

Guided in the two guide rails 12a/13a and 14a/15a, a first and second slider 12b/13b and a third and fourth slider 14b and 15b run over the two Halbach arrays. The sliders 12b/15b are identical in design and can be moved on the respective guide rail and over the respectively associated Halbach array independently of one another in both directions of the Halbach array within a predetermined movement range.

They respectively comprise a linear motor 12b.2-15b.2 as active drive component and a guide carriage (not separately labelled) fixedly connected to it for precise linear guiding of the respective linear motor in the guide rail associated with it. A person skilled in the art is familiar with drives of the type shown here, which comprise a Halbach array as passive drive component and a linear motor with induction coils as active drive component, and they are therefore not explained in more detail here. However, reference is made to some comments on the drive concept above.

Rotary joints 16j-16m are provided near the edges facing each other of the sliders 12b and 13b on the one side and the sliders 14b and 15b on the other side, which joints form parts of a parallel kinematic unit 16, which is rotatably mounted between the sliders 12-15. It comprises, as already shown in FIG. 3, a load platform 16a as well as four connecting arms 16b/16e and four further rotary joints 16f—16i, which rotatably connect the load platform 16a to the ends of the connecting arms 16b/16e respectively lying on it.

The load platform 16a can directly accommodate a load, for example a workpiece to be machined or an object to be measured, and can move it into a precise predetermined position thanks to suitable control of the drives. However, it can also support additional positioning devices, such as a rotary table or a Z-axis positioning device, which, in conjunction with the proposed planar positioning device, also provide the option of adjusting the angle and/or height of the object to be positioned. However, further positioning devices of this type are not the subject of the present invention and are therefore not described further here.

Each of the sliders 12b-15b of the linear guides/drives carries a position sensor 12c-15c. The position sensors are optical sensors, which are designed to detect the respectively associated linear position scale 18 or 19 and register the position of the respective slider in its linear guide during each drive operation. Furthermore, as shown in FIG. 5, a two-dimensional position scale 20 is applied to the surface of the load platform 16a opposite the load-bearing surface, and a position sensor 21 is provided “fixed in space” (i.e. in a fixed position in relation to the driven parallel kinematic unit), which is designed to detect the 2D position scale 20 and directly registers the position of the load platform in the positioning plane (XY plane).

FIG. 6 schematically shows in a type of functional block diagram how the position sensors 12c-15c on the linear guides/drives 12-15, on the one hand, and the position sensor 21 below the load platform of the parallel kinematic unit 16, on the other hand, are connected to corresponding inputs of a position determining device 22 of the planar positioning device.

Evaluation programs used as a basis for evaluating the position signals in a processor 22b are stored in a program memory 22a of the position determining device for implementing the various options explained above for evaluating position signals of the different, partially redundant, position sensors. The position determining device can supply a plurality of datasets Di, which can be used to display the position of the object to be positioned or else to control or regulate the drives or else to calibrate the sensors, as explained above.

The embodiment of the invention is not limited to the aspects highlighted above and the illustrated exemplary embodiment, but is also possible in a large number of variations which are within the scope of the appended claims.

1. Planar positioning device for positioning loads in a predetermined plane, having
a base plate having a flat surface that extends parallel to and at a specific distance from the predetermined positioning plane, thus defining same,
four identical linear guides/drives, two of which are attached to or on the base plate collinearly and at a distance parallel to the other two, and
a parallel kinematic unit which comprises a load platform, is arranged between the parallel linear guides/drives, and is rotationally connected to the sliders of all linear drives via one passive joint each.

2. Planar positioning device according to claim 1, wherein the load platform of the parallel kinematic unit is designed as a rectangular, in particular square, plate, on or near the corners of which a passive joint is provided, with which a connecting arm of the parallel kinematic unit is respectively rotationally connected, the other end of which is connected to the joint on one of the linear drives.

3. Planar positioning device according to claim 2, wherein all connecting arms are identical.

4. Planar positioning device according to claim 1, wherein the collinear linear guides/drives respectively comprise a common linear guide and two linear motors with guide carriages as sliders, which are arranged spaced apart on the guide and moveable collinearly and independently of one another in both directions.

5. Planar positioning device according to claim 4, wherein the collinear linear guides/drives comprise a Halbach array of permanent magnets that is common to both linear motors and extends substantially over the entire length of the linear guide.

6. Planar positioning device according to claim 1, wherein each of the linear guides/drives is associated with position sensors for detecting the position of the respective slider.

7. Planar positioning device according to claim 6, wherein the position sensors of the collinear linear guides/drives have a linear, in particular optical, position scale that is common to both sliders, and each slider designed as a linear motor is associated with a position sensor, in particular an optical position sensor, designed to detect the linear position scale.

8. Planar positioning device according to claim 1, wherein a two-dimensional, in particular optical, position scale is provided on a surface of the load platform and a position sensor, in particular an optical position sensor, is associated therewith and is designed to detect the two-dimensional position scale.

9. Planar positioning device according to claim 8, further comprising a position determining device, which is connected at the input side to the position sensors on the linear guides/drives and the three-dimensional position sensor and is designed for pre-determined processing of the respective position signals, in particular selectively only the signals of the position sensors on the linear guides/drives or only the position signals of the two-dimensional position sensor on the load platform or the signals of all position sensors combined or in the sense of a calibration of the one sensor type by the other sensor type.

10. Workbench having a planar positioning device according to claim 1.
